(19) United States
(12) Patent Application Publication
(10) Pub. No.: US 2005/0109917 A1
(43) Pub. Date: May 26, 2005

(54) Multi-spectral imaging with almost-full fill-factor using 3D pixels

(76) Inventor: Hon-Sum P. Wong, Chappaqua, NY (US)

Correspondence Address: Moser, Patterson & Sheridan, Suite 100, 595 Shrewsbury Avenue, Shrewsbury, NJ, 07702, US

(21) Appl. No.: 10/722,749

(22) Filed: Nov. 26, 2003

(51) Int. Cl. H01L 27/00

(52) U.S. Cl. 250/208.1

(57) ABSTRACT

Image systems having three dimensional pixels. Each pixel is comprised of a substrate and a three dimensional stack of color sensors. Wavelength sensitive color reflectors are inserted between the individual color sensors and the semiconductor substrate. Incoming photons are partially converted into an electric charge in a color sensor. The unabsorbed portion is wavelength-selectively reflected to produce additional charge in the color sensor. The transmitted portion passes into a lower color sensor to produce an electric charge in that lower color sensor. The unabsorbed portion is wavelength-selectively reflected by another color reflector to produce additional charge in the lower color sensor. The process repeats for still lower color sensors/color reflectors. The substrate includes logic to interrogate the color sensors. Electrical conductors connect the substrate to the individual color sensors.

### BACKGROUND OF THE INVENTION

1. Field of the Invention

Embodiments of the present invention generally relate to solid-state imaging devices. More specifically, the present invention relates to pixel-based, three-dimensional, high-fill factor, multiple wavelength imaging sensors.

2. Description of the Related Art

Prior art solid-state color imaging is usually performed using pixel sensor elements and absorptive color filters, e.g., red, green, and blue filters. Those color filters can be either located on-chip with the pixel sensor elements or off-chip. The color filters and the pixel sensor elements are typically arranged in a pattern such that a tristimulus response is produced over a small area which forms a pixel. Thus, a pixel is comprised of three sub-pixels, one for each tristimulus color. A color image is produced by sensing the wavelengths that pass though the color filters and then interpolating the color information from adjacent sensor elements.

While prior art solid-state color imaging systems are beneficial, they have at least two serious limitations. First, the color information that is obtained from a sensor element is less than optimal because each color's sensor element takes up only a part of a pixel's area. For example, a single pixel requires red, green, and blue color filters, each with their own color sensor. Thus, the color image resolution of an imager having M×N color filters is actually well below M×N pixels.

The other problem with prior art solid-state color imaging systems is that the amount of light that is received by each sensor element is less than the amount of light impinging upon each pixel sensor element. This is because some of the incoming light is filtered away by the absorptive color filter and because pixel sensor elements have fill factors (the ratio of a light sensitive area to the total sensor area) that are substantially less than 100%. In fact, about ⅔ of the incoming light is absorbed by an absorptive color filter, and fill factors of less then 75% are common.

Therefore, in view of the limitations of prior art solid-state color imaging systems, sensor elements having high fill factors and high color sensitivity would be beneficial.

### SUMMARY OF THE INVENTION

In one embodiment, the principles of the present invention generally enable solid-state color imaging systems having high color resolution, high fill factors, and high color sensitivity.

Embodiments of the present invention have pixels comprised of a semiconductor substrate and a three dimensional stack of color sensors. Between each pair of color sensors is a wavelength sensitive color reflector that reflects a predetermined color. Another wavelength sensitive color reflector is between the color sensor stack and the semiconductor substrate. The pixels are generally formed such that each color sensor has an almost-full fill-factor.

In some embodiments the thickness of the individual photo-sensitive portions of the color sensors are tailored such that the first color sensor is most sensitive to wavelengths reflected by a first color reflector, the second color sensor is most sensitive to the wavelengths reflected by a second color reflector, and the third color sensor is most sensitive to wavelengths reflected by a third color reflector.

Embodiments of the present invention include color sensors having sensor elements and row and column switches. The row and column switches are electrically connected to logic on the semiconductor substrate via vertical electrical conductors. The sensor elements and row and column switches are configured such that charges collected by the color sensors can be selectively applied to circuitry on the semiconductor substrate.

In embodiments of the present invention the wavelength sensitive color reflectors are comprised of dielectric or semiconductor layers, each having a controlled thickness, to form Bragg reflectors (interference filters).

The principles of the present invention are not limited to tristimulus applications (such as red, green, and blue color sensors) and can, in fact, be extended to include pixels having more (or less) than three color sensors. In some embodiment of the present invention color reflectors are used to form a multi-spectral imager having pixels that are sensitive to a plurality of light spectrums and having a plurality of pass-bands.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an image sensor that is in accord with the principles of the present invention;

FIG. 2 shows a basic block diagram of a single color sensor; and

FIG. 3 illustrates a pixel that is in accord with the principles of the present invention.

To facilitate understanding, identical reference numerals have been used, wherever possible, to designate identical elements that are common to the figures.

### DETAILED DESCRIPTION OF THE PREFERRED EMBODIMENT

The present invention provides for novel imaging devices that have pixels comprised of a three-dimensional stack of color sensors on a semiconductor substrate. Wavelength sensitive color reflectors, each of which reflects a predetermined color, are located a) between pairs of color sensors and b) between the color sensor stack and the semiconductor substrate. Light that reflects from the color reflectors illuminates an associated color sensor while light that passes through a color reflector passes into a lower color sensor. Thus, the color reflectors provide for color filtering. Some embodiments of the present invention include decoder switches on the color sensors and decoder logic on the semiconductor substrate to interrogate the light-induced charges collected by the color sensors.

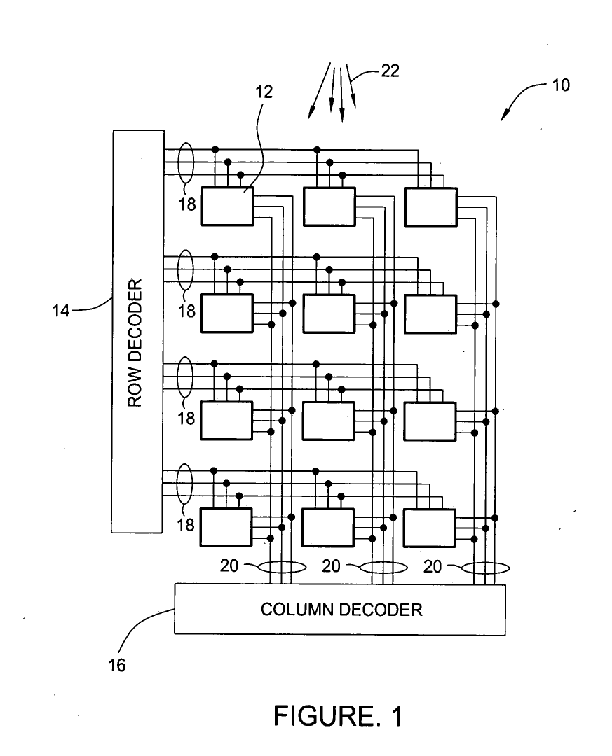

FIG. 1 schematically illustrates an image sensor 10 having a matrix of pixels 12 and associated decoding logic. The decoding logic is comprised of a row decoder 14 and a column decoder 16. Row buses 18 and column buses 20 interconnect the pixels 12 with the decoding logic. Incoming light 22 generates electric charges in the pixels 12 such that the amount of generated electric charge depends on the intensity of the incoming light 22. Those charges, which are individually produced for blue, green, and red wavelengths (as is subsequently explained), are collected within the pixels 12. When the row decoder 14 applies electric potentials to a row bus 18, the collected charges of the pixels 12 that are connected to that row bus 18 can be read out on the column bus 20. The pixels 12 are comprised of a three dimensional stack of color sensors on a semiconductor substrate.

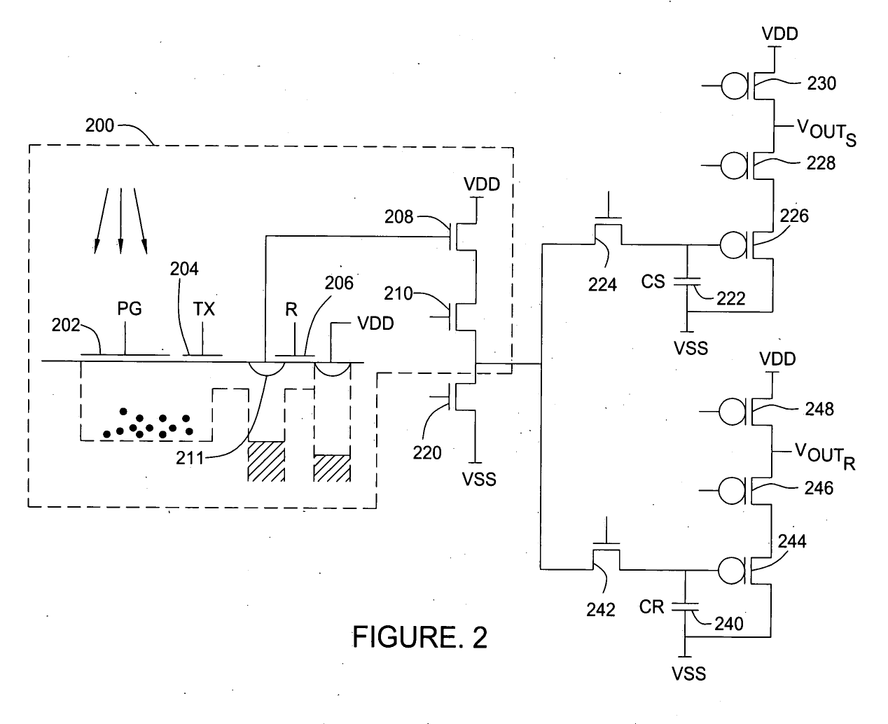

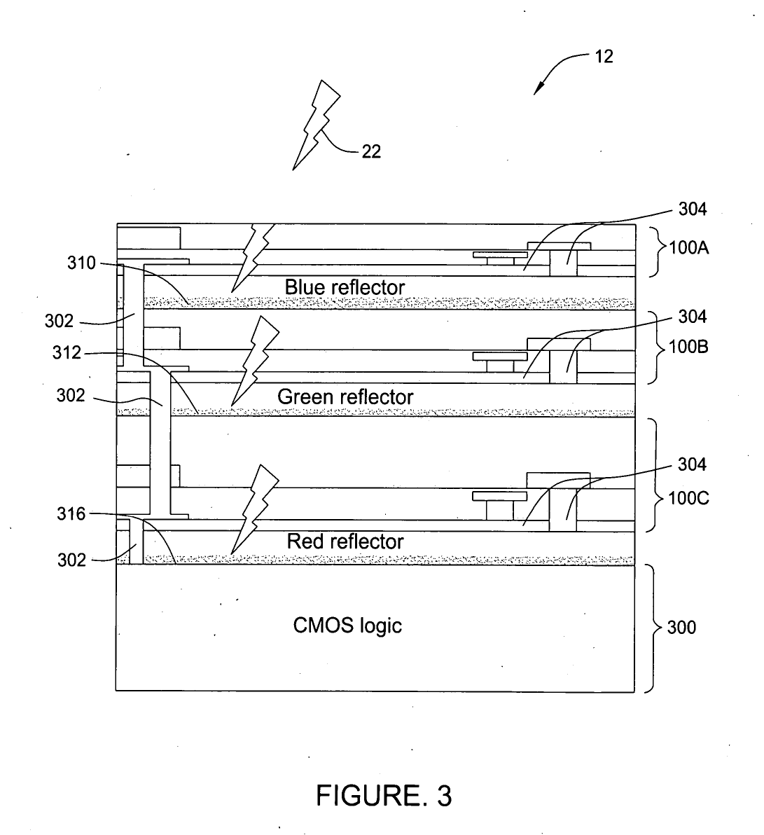

FIG. 2 helps illustrate the operation of a single color CMOS active sensor 200 of a single pixel 12 (which has three stacked color sensors 200). The sensor 200 is connected to a readout portion that is located on a semiconductor substrate (which is shown in FIG. 3). The sensor 200 includes a photo-gate 202 (also designated PG), a transfer gate 204 (also designated TX), a reset transistor 206 (also designated R), a source-follower 208, a row-selection transistor 210, and a floating diffusion output node 211.

The readout portion includes a load transistor 220 that connects to the row-selection transistor 210. Also connected to the row-selection transistor 210 is a two branch network that stores signal and reset levels. The signal branch includes a sample and hold signal capacitor 222 (also designated CS) that is connected to a signal sampling switch 224, which connects to the load transistor 220, and to a signal source-follower 226. The signal source-follower 226 is connected to a series connection of a signal column-selection switch 228 and a signal load transistor 230. The reset branch includes a sample and hold reset capacitor 240 (also designated CR) that is connected to a reset sampling switch 242, which connects to the load transistor 220, and to a reset source-follower 244. The reset source-follower 244 is connected to a series combination of a reset column-selection switch 246 and a reset load transistor 248. The readout circuits are common to an entire column of pixels, except the load transistors 230 and 248, which are common to the entire array.

In operation, during an initial integration period the transfer gate 204 (TX) and the load transistors 220, 230, and 248 are biased at 2.5V (half V_{DD}), the photo-gate 202 (PG) is biased high (V_{DD}), the transfer gate 204 is biased LOW (V_{SS}), and the reset transistor 206 is biased at 2.5V to act as a lateral anti-blooming drain. During this integration period, incident light 22 that is radiated onto the photo-gate 202 (PG) generates electron-hole pairs, the electrons of which are collected under the photo-gate 202. Following the integration period, an entire row of pixels is simultaneously read out. First, the row selection switch 210 of each pixel of a row is enabled. Then, the pixel output node 211 is reset by briefly pulsing the gate of the reset transistor 206 (R) HIGH to reset the floating diffusion output node 211 to approximately 3.5V. The output of the first source follower 208 is then applied to reset capacitor 240 (CR) by turning on the reset sampling switch 242. Then, the photo-gate 202 (PG) is pulsed low and the transfer gate 204 (TX) is turned ON to transfer the photo-induced charge to the floating diffusion output node 211. The output of the floating diffusion output node 211 is then sampled onto the sample and hold signal capacitor 222 (CS) by turning on signal sampling switch 224. The stored reset and signal levels are then scanned out by the reset source-follower 244 and by the signal source-follower 226 by turning on the reset column-selection switch 246 and the signal column-selection switch 228. The voltage difference between the output Vout_{R} of the reset column-selection switch 246 and the output Vout_{S} of the signal column-selection switch 228 is a measure of the incident light 22.

As previously noted, the pixels 12 are comprised of a stack of three color sensors 100. FIG. 3 shows a pixel 12 and its stack of colors sensors 100A, 100B, and 100C. The color sensor stack is located on a semiconductor substrate 300 that includes CMOS logic and readout devices that selectively interrogate the color sensors 100A-100C. Disposed between color sensors 100A and 100B is a blue reflector 310, disposed between color sensors 100B and 100C is a green reflector 312, and disposed between color sensor 100C and the semiconductor substrate 300 is a red reflector 316. Various conductors 302 and metallic patterns 304 electrically connect the color sensor circuitry to the semiconductor substrate 300.

In operation, incoming light 22 (photons) are partially absorbed as they pass through color sensor 100A. Those absorbed photons are converted to an electric charge. The unabsorbed light not reflected by the blue reflector 310 is transmitted through that reflector. The reflected photons produce additional electric charge in the color sensor 100A, while the transmitted portion passes into color sensor 100B. As the incoming photons pass through the color sensor 100B they are partially absorbed and converted to an electric charge. The portion that is not reflected by the green reflector 312 is transmitted through that reflector. The reflected photons produce additional electric charge in color sensor 100B, while the transmitted portion passes into color sensor 100C. As the incoming photons pass through the color sensor 100C they are partially absorbed and converted to an electric charge. The portion that is not absorbed is reflected by the red reflector 316. The reflected photons produce additional electric charge in the color sensor 100C.

In the foregoing fashion the relevant reflector provides for the light to effectively pass through the relevant active pixel layer twice, once when the light is incoming and the second after being reflected. Thus, first and second portions of the incoming light are converted into a first electric charge; third and fourth portions are converted into a second electric charge; and fifth and sixth portions are converted into a third electric charge. Those electric charges are subsequently interrogated by logic to determine the intensity of a first, a second, and a third color spectrum. If more than three sensors are stacked the remaining light, a seventh portion, passes through a material layer to another sensor.

The foregoing has described reflecting part of incoming light so that it passes through a semiconductor layer twice. However, a sensor can be constructed such that it forms a Fabry-Perot cavity. This can be accomplished by having the reflectors act mirrors as light passes in either direction through a layer. For example, having the blue reflector 310 and the green reflector 312 act as mirror for the color sensor 100B.

The thicknesses of the photo-sensitive portion of the color sensors 100A-100C are tailored such that the photo-sensitive portion of color sensor 100A is thinnest and more sensitive to short wavelengths (blue), the photo-sensitive portion of color sensor 100B is thicker and more sensitive to somewhat longer wavelengths (green), while the photo-sensitive portion of color sensor 100C is thickest and more sensitive to the longest wavelengths (red). Thus the color sensors are formed to match the color reflectors.

The image sensor 10 is formed by wafer bonding color sensors 100A-100C together and onto the semiconductor substrate 300. Conventional semiconductor fabrication processes are used to form the color sensors, to form the semiconductor substrate 300, and to wafer bond the various layers together. The color reflectors 310, 312, and 316 are Bragg reflectors (interference filters) formed on the color sensors by dielectric layers having controlled thicknesses. The color reflectors can be formed on the individual color sensors by depositing dielectric layers with suitable refractive indices to achieve the desired reflection properties.

While the foregoing has described an image sensor 10 having three color sensors 100A-100C and color reflectors 310, 312, and 316, the principles of the present invention extend to image sensors having other than three sensors. Some embodiments of the present invention use color sensors and color reflectors to form multi-spectral imagers having pixels that are sensitive to a plurality of light spectrums and that have a plurality of pass-bands. Thus, the present invention is not limited to red, green, and blue color sensors. Since each pixel senses the full spectral (color) information, the pixel resolution is higher than in conventional imagers. This is especially true if the number of spectral bands to be imaged is substantially larger than three. In multi-spectral imaging, it is common to capture 10 spectral bands. Such applications can benefit from the principles of the present invention. Furthermore, the pixels can be formed such that each color sensor has an almost-full fill-factor.

While the foregoing is directed to embodiments of the present invention, other and further embodiments of the invention may be devised without departing from the basic scope thereof, and the scope thereof is determined by the claims that follow.

1. An imaging sensor comprising a plurality of pixels, where each of said pixels comprises a semiconductor substrate and a three-dimensional stack of color sensors on the semiconductor substrate.

2. The imaging sensor of claim 1, further including a plurality of color reflectors, wherein each pair of color sensors is separated by one of said color reflectors, and wherein the semiconductor substrate and the three-dimensional stack of color sensors is separated by one of said color reflectors.

3. The imaging sensor of claim 2, wherein each color reflector reflects a different color spectrum.

4. The imaging sensor of claim 3, wherein each color reflector is a Bragg reflector.

5. The imaging sensor of claim 1, further including connectors that electrically connect each color sensor to logic on the semiconductor substrate.

6. The imaging sensor of claim 1, wherein each color sensor includes a photo-sensor and a plurality of transistors for interrogating photo-induced charges generated by said photo-sensor.

7. The imaging sensor of claim 6, wherein each color sensor is a CMOS active sensor.

8. The color imaging devices of claim 6, wherein said semiconductor substrate includes row decoder and a column decoder.

9. The color imaging devices of claim 3, wherein the color reflector that reflects the longest set of wavelengths is between the semiconductor substrate and the three-dimensional stack of color sensors, and wherein the color reflector that reflects the shortest set of wavelengths is furthest from said semiconductor substrate.

10. The color imaging devices of claim 9, wherein each color sensor has a different thickness, wherein the thickest color sensor is adjacent to said color reflector that reflects the longest set of wavelengths, and wherein the thinnest color sensor is furthest from said semiconductor substrate.

11. An imaging sensor comprising:
a semiconductor substrate having a plurality of crossing row and column conductors;
a row decoder for selectively applying potentials to a set of row conductors;
a column decoder for selectively reading charges on a set of column conductors;
a pixel matrix comprised of a plurality of pixels, where each of said pixels is located adjacent to one of said crossings of row and column conductors, wherein each pixel includes a three-dimensional stack of color sensors on said semiconductor substrate; and
electrical connectors that electrically connect each color sensor to one of said row conductors and to one of said column conductors.

12. The imaging sensor of claim 11, wherein each pixel includes a plurality of color reflectors, wherein each pair of color sensors is separated by one of said color reflectors, and wherein the semiconductor substrate and the three-dimensional stack of color sensors is separated by one of said color reflectors.

13. The imaging sensor of claim 12, wherein each color reflector reflects a predetermined color spectrum.

14. The imaging sensor of claim 13, wherein each color reflector reflects a different color spectrum, wherein one of said color reflectors that reflects a longest set of wavelengths is between the semiconductor substrate and the three-dimensional stack of color sensors, and wherein one of said color reflectors that reflects a shortest set of wavelengths is furthest from said semiconductor substrate.

15. The imaging sensor of claim 14, wherein each color sensor has a photo-sensor, wherein the color sensor adjacent said color reflector that reflects the longest set of wavelengths has a photo-sensor that is thicker than the photo-sensor of the color sensor furthest from said semiconductor substrate.

16. The imaging sensor of claim 13, wherein each color reflector is Bragg reflector.

17. The imaging sensor of claim 11, wherein each color sensor includes a photo-sensor and a plurality of transistors for interrogating photo-induced charges generated by said photo-sensor.

18. A method of imaging, comprising the steps of:
converting a first portion of incoming light into a first electric charge;
reflecting a second portion of the incoming light and converting said second portion into additional first electric charge;
passing the remaining incoming light through a material while reflecting the second portion;
converting a third portion of incoming light into a second electric charge;
reflecting a fourth portion of the incoming light and converting said fourth portion into additional second electric charge;
passing the remaining incoming light through a material while reflecting the fourth portion;
converting a fifth portion of incoming light into a third electric charge; and
reflecting a sixth portion of the incoming light and converting said sixth portion into additional third electric charge.

19. The method of imaging according to claim 18, further including the steps of interrogating said first electric charge to determine the intensity of a first color spectrum, interrogating said second electric charge to determine the intensity of a second color spectrum, and interrogating said third electric charge to determine the intensity of a third color spectrum.

20. The method of imaging according to claim 18, further including passing the remaining incoming light through a material while reflecting the sixth portion.
